(19) United States
(12) Patent Application Publication
(10) Pub. No.: US 2010/0009510 A1
(43) Pub. Date: Jan. 14, 2010

(54) Method of manufacturing semiconductor device

(75) Inventor: Takasuke Hashimoto, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/458,336

(22) Filed: Jul. 8, 2009

(30) Foreign Application Priority Data
Jul. 9, 2008 (JP) 2008-179563

(51) Int. Cl. H01L 21/02

(52) U.S. Cl. 438/382; 257/E21.004

(57) ABSTRACT

A method of manufacturing a semiconductor device including implanting an impurity ion into a predetermined region of a semiconductor layer using a resist film as a mask, wherein in case when a mask data ratio for implanting the impurity ion only into the predetermined region in the resist film is less than a first reference value, a dummy ion implantation region, into which the impurity ion is also implanted in addition to the predetermined region, is added in a region other than the predetermined region so that a mask data ratio becomes larger than a second reference value which is equal to or larger than the first reference value, the mask data ratio indicating a ratio of an opening with respect to an entire region of a reticle region corresponding to the reticle.

### BACKGROUND OF THE INVENTION

This application is based on Japanese patent application No. 2008-179563, the content of which is incorporated herein by reference.

### TECHNICAL FIELD

The present invention relates to a method of manufacturing a semiconductor device.

### RELATED ART

As a resistive element that is used in a semiconductor integrated circuit, a polysilicon resistive element that is formed by implanting an impurity ion into a polysilicon layer has been known. This polysilicon resistive element is manufactured in accordance with the following sequence. First, a polysilicon layer is formed on an entire surface of a substrate. Next, after coating the entire surface of the substrate with a resist film, only a predetermined region to be a resistive element is opened using a photolithographic technique. Using the resist film as a mask, an impurity ion, such as boron, is implanted into the entire surface of the substrate. Thereafter, the resist film is removed and the polysilicon layer is patterned in a predetermined shape, thereby activating the implanted impurity ion using thermal treatment. Further, an insulating interlayer is formed on the polysilicon layer, a contact opening is formed in the insulating interlayer, and a conductive material, such as aluminum, is buried in the opening to form an interconnection.

However, the inventor has found that a spatial variation is generated in an effective implantation dose amount of an introduced impurity ion, when an impurity ion is implanted into a semiconductor layer in order to form the polysilicon resistive element. For this reason, when a resistive element is formed in each chip formation region of a semiconductor wafer that has a plurality of chip formation regions, a spatial variation may be generated in a resistance value. As the result that is obtained by performing various studies on the above reason, the inventors have found that the above phenomenon is notably generated, when a region where the impurity ion is implanted is narrow.

### SUMMARY OF THE INVENTION

In an embodiment, there is provided a method of manufacturing a semiconductor device including implanting an impurity ion into a predetermined region of a semiconductor layer using a resist film as a mask, wherein in case when a mask data ratio for implanting the impurity ion only into the predetermined region in the resist film is less than a first reference value, a dummy ion implantation region, into which the impurity ion is also implanted in addition to the predetermined region, is added in a region other than the predetermined region so that a mask data ratio becomes larger than a second reference value which is equal to or larger than the first reference value, the mask data ratio indicating a ratio of an opening with respect to an entire region of a reticle region corresponding to the reticle.

Any combination of the above configurations and a conversion between the method and the apparatus of the present invention are effective as aspects of the present invention.

According to the present invention, when the impurity ion is implanted, it is possible to prevent generation of a spatial variation in an effective implantation dose amount.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a flowchart illustrating an example of a sequence of manufacturing a semiconductor device according to an embodiment of the present invention;

FIGS. 2A to 6B are cross-sectional views illustrating an example of a sequence of manufacturing a semiconductor device according to an embodiment of the present invention;

FIG. 7 is a flowchart illustrating a sequence of setting a dummy ion implantation region;

FIG. 8 is a plan view illustrating a dummy ion implantation region;

FIG. 9 is a plan view illustrating a resist film to form a pattern shown in FIG. 8;

FIG. 10 is a diagram illustrating a variation relationship between a mask data ratio and a sheet resistance value;

FIGS. 11A and 11B are a plan view illustrating a reticle region of a semiconductor device;

FIG. 12 is a diagram illustrating a variation relationship between a data ratio and sheet resistance;

FIG. 13 is a diagram illustrating a variation relationship between a data ratio and sheet resistance;

FIG. 14 is a cross-sectional view schematically illustrating a state where a resist film for impurity ion implantation is formed on a polysilicon layer;

FIGS. 15A and 15B are cross-sectional views schematically illustrating a state where a resist film for impurity ion implantation is formed on a polysilicon layer;

FIG. 16 is a plan view illustrating a resistance element region; and

FIG. 17 is a plan view illustrating a resist film to form a pattern shown in FIG. 16.

### DETAILED DESCRIPTION

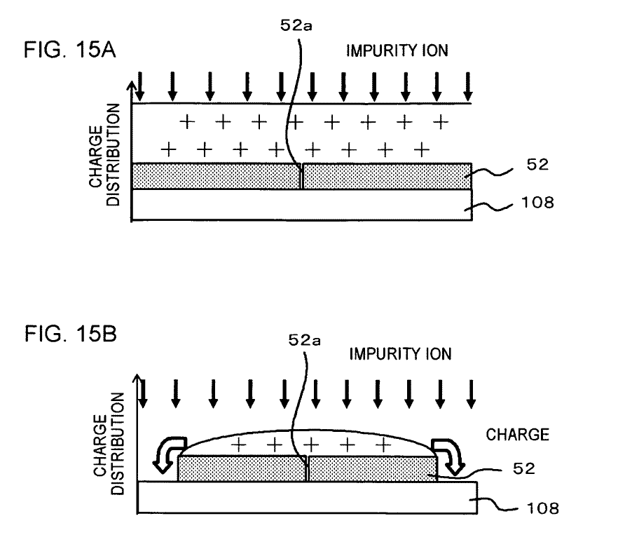

Before describing of the present invention, the conventional problems will be explained in detail with reference to FIGS. 15A and 15B in order to facilitate the understanding of the present invention.

FIGS. 15A and 15B are cross-sectional views schematically illustrating a state where a resist film 52 for impurity ion implantation is formed on a polysilicon layer 108. For example, when an impurity ion is implanted to form a polysilicon resistive element, a dedicated resist film is used to implant only an impurity ion for a resistive element. For this reason, a region where the impurity ion is implanted is extremely narrowed. As such, when the region where the impurity ion is implanted is extraordinarily narrow, as shown in FIG. 15A, an opening 52a of a resist film 52 is extraordinarily narrow, and almost the entire surface of the polysilicon layer 108 may be covered with the resist film 52. For this reason, charges may be collected on the resist film 52 and the impurity ion may not be implanted into the opening 52a. As a result, it is considered that a concentration of the impurity ion that is implanted into the polysilicon layer 108 from the narrow opening 52a is lowered.

Further, a region where an impurity ion is implanted may be densely and roughly disposed on the substrate. Even in this case, if a region where the polysilicon layer 108 is covered with the resist film 52 is large, the charges may be collected on the resist film 52. For this reason, as shown in FIG. 15B, the impurity ion is implanted into the polysilicon layer 108 in a place where an impurity ion implantation region is large. However, the impurity ion may not be implanted into the extraordinarily narrow opening 52a, and a spatial variation may be generated in an effective implantation dose amount of the introduced impurity ion.

In order to solve this problem, the inventors have found that it is possible to decrease the amount of charges on the resist film, even when the region where the impurity implantation region is narrow and the opening of the resist film is narrow, by increasing the size of the opening of the resist film so that the charges accumulated in the surface of the resist film are moved to a semiconductor layer of an impurity ion implantation object and have reached the prevent invention.

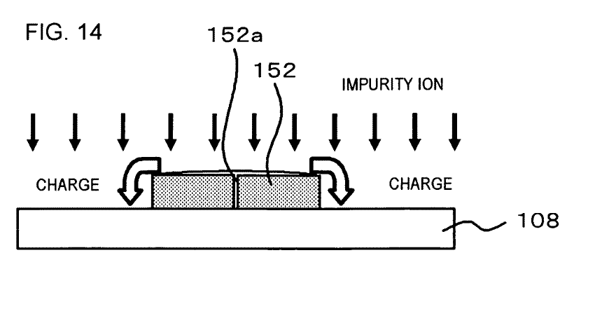

In this way, the charges that are accumulated in the surface of the resist film 52 described using FIG. 15 are moved to the polysilicon layer 108 as the semiconductor layer, so that the amount of charges on the resist film can be decreased, and the impurity ion can be implanted from the opening. This example is shown in FIG. 14. As shown in FIG. 14, when the size of the region where the polysilicon layer 108 is exposed is increased, the charges that are accumulated on the resist film 152 can be released to the polysilicon layer 108, and the charges on the resist film 152 can be decreased. As a result, even though the opening 152a is narrow, the impurity ion can be implanted into the polysilicon layer 108 from the opening 152a. In addition, it is possible to decrease a spatial variation in an effective implantation dose amount of the impurity ion that is introduced into the polysilicon layer 108.

In the related art, when a metal material is buried in a concave portion, and a metal material outside the concave portion is removed using a chemical mechanical polishing (CMP) technique to perform a planarizing process, in the case where a ratio of a pattern of the concave portion is excessively large or small, the metal material may be excessively removed. In order to solve this problem, techniques for introducing a dummy pattern have been known (for example, refer to Japanese Patent Application Laid-Open (JP-A) Nos. 2006-344176, 2006-108571, and 2006-80562). In the related art, however, when the impurity ion is implanted, a method that resolves a problem where a variation may be generated in an effective implantation dose amount is not studied.

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, exemplary embodiments of the present invention will be described with reference to the accompanying drawings. In all drawings, the same constituent elements will be denoted by the same reference numerals and the description thereof will not be repeated.

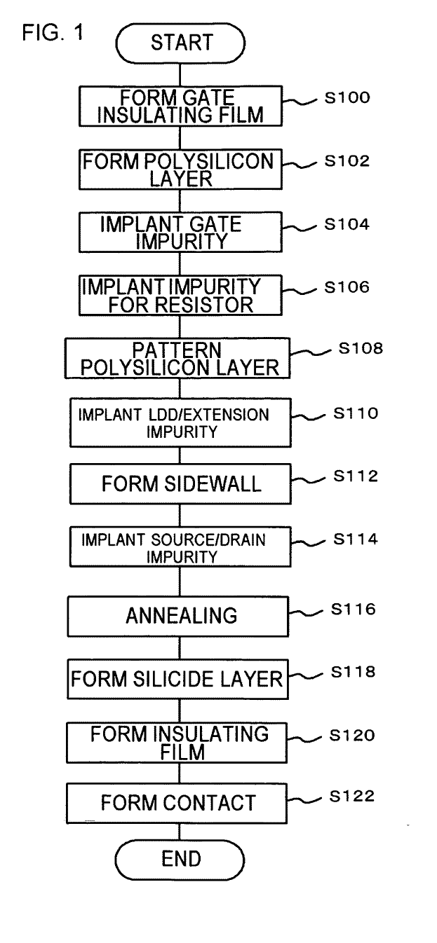

Hereinafter, the case where a semiconductor layer is a polysilicon layer formed on a semiconductor substrate is exemplified. First, a sequence, which is used when an impurity ion is implanted into the polysilicon layer that is formed on the semiconductor substrate and a resistive element and a gate electrode are formed, is described. FIG. 1 is a flowchart illustrating the above sequence.

A gate insulating film is formed on the entire surface of the semiconductor substrate (S100) and a polysilicon layer is formed on the gate insulating film (S102). Next, an impurity ion is implanted into a region of the polysilicon layer to be a gate electrode thereafter (S104). Next, the impurity ion is implanted into a region of the polysilicon layer to be a resistor thereafter (S106). Next, the polysilicon layer is patterned in a gate shape and a resistor shape (S108). Next, using the polysilicon layer having the gate shape as a mask, the impurity ion is implanted to form an LDD/extension region (S110). Next, sidewalls are formed at the sides of the polysilicon layer that has the gate shape and the resistor shape (S112). Thereafter, using the polysilicon layer having the gate shape and the sidewall as a mask, the impurity ion is implanted to form a source/drain region (S114). At this time, a high-concentration impurity ion is implanted into a portion of the polysilicon layer having the resistor shape to be connected to a contact thereafter. Next, annealing is performed (S116) and then a silicide layer is formed (S118). Next, an insulating film that covers the polysilicon layer is formed (S120), and a contact hole is formed in the insulating film to form a contact (S122).

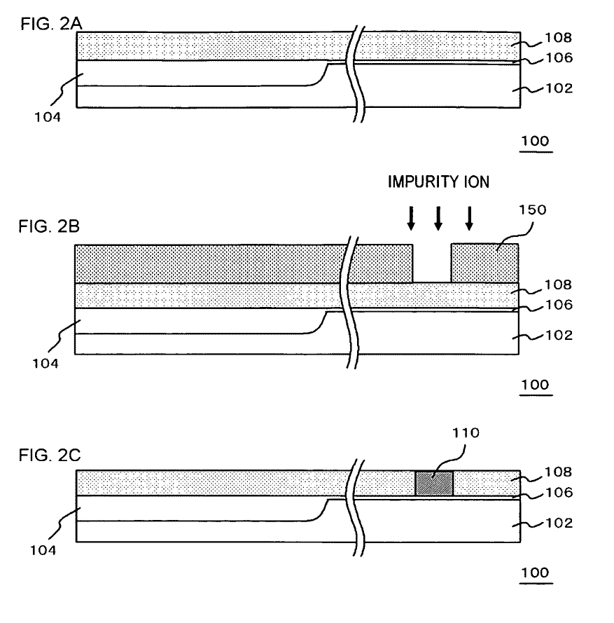

Next, the sequence will be specifically described using the accompanying drawings. FIGS. 2A to 6B are cross-sectional views illustrating the above sequence.

An element isolation insulating film 104 is formed on a portion of a surface of a semiconductor substrate 102 (substrate). A gate insulating film 106 is formed on the entire surface of the semiconductor substrate 102. Next, a polysilicon layer 108 is formed on the entire surface of the semiconductor substrate 102. This state is shown in FIG. 2A.

Next, a resist film 150 is formed on the polysilicon layer 108. The resist film 150 is exposed and developed using a reticle to form an opening at a region becoming a gate electrode of a transistor thereafter. At this time, a region that corresponds to one reticle is called a reticle region. Next, using the resist film 150 as a mask, the impurity ion is implanted into the entire surface of the semiconductor substrate 102 (refer to FIG. 2B). Next, the resist film 150 is removed. As a result, the impurity ion is selectively implanted into the gate electrode region 110 (refer to FIG. 2C).

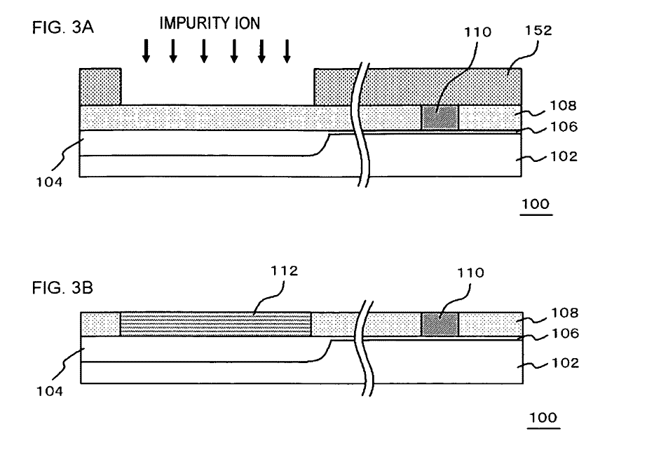

Next, the impurity ion is implanted into the entire surface of the semiconductor substrate 102, using a resist film 152 (insulating film) where a region to be a resistive element thereafter is selectively opened as a mask (refer to FIG. 3A). Next, the resist film 152 is removed. As a result, the impurity ion is selectively implanted into the resistive element region 112 (refer to FIG. 3B).

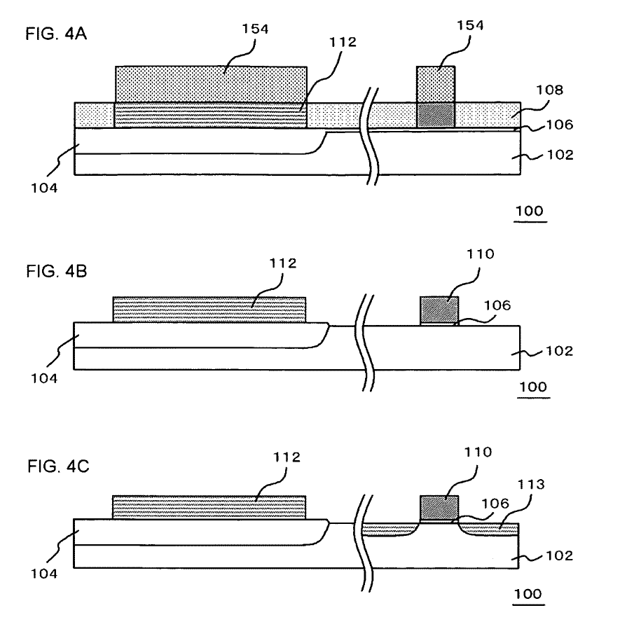

Next, the polysilicon layer 108 and the gate insulating film 106 are etched using the resist film 154 to pattern the polysilicon layer 108 in the gate electrode shape and the resistive element shape (refer to FIGS. 4A and 4B). Next, using the gate electrode region 110 as a mask, the impurity ion is implanted into the entire surface of the semiconductor substrate 102, thereby forming an extension region 113 (refer to FIG. 4C).

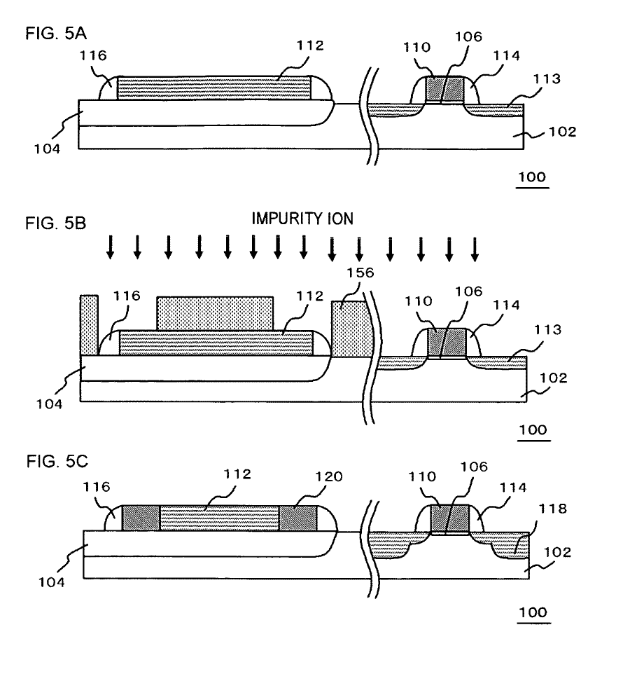

Next, a sidewall 114 and a sidewall 116 are formed at the sides of the gate electrode region 110 and the resistive element region 112, respectively (refer to FIG. 5A). Next, using a resist film 156 that masks a predetermined region of the resistive element region 112 and a region other than the source/drain region, the impurity ion is implanted into the entire surface of the semiconductor substrate 102, and a high resistance region 120 is formed in the resistive element region 112. A source/drain region 118 is formed at both sides of the sidewall 114 of the gate electrode region 110 (refer to FIGS. 5B and 5C).

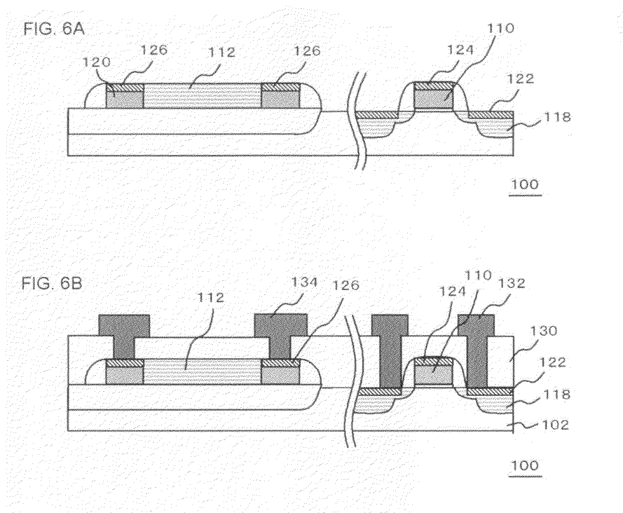

Next, silicide layers 122, 124, and 126 are formed on the source/drain region 118, the gate electrode region 110, and the resistive element region 112, respectively (FIG. 6A) Next, an insulating interlayer 130 that buries the gate electrode region 110 and the resistive element region 112 is formed. Next, contact holes re formed in the insulating interlayer 130, and the insulating interlayer 130 is buried by a conductive material, thereby forming contacts 132 and 134 (refer to FIG. 6B).

Meanwhile, in the above sequence, for example, a ratio of the region where the resistive element region 112 is formed with respect to the entire surface of the substrate is extraordinarily small. Further, in the process of selectively implanting the impurity ion into the resistive element region 112, since a dedicated photo resist film is used only to implant the impurity ion into the resistive element region 112, a mask data ratio indicating a ratio of the opening with respect to the entire portion of the reticle region used when the opening is formed in the resist film may be extraordinarily low as less than 0.1%.

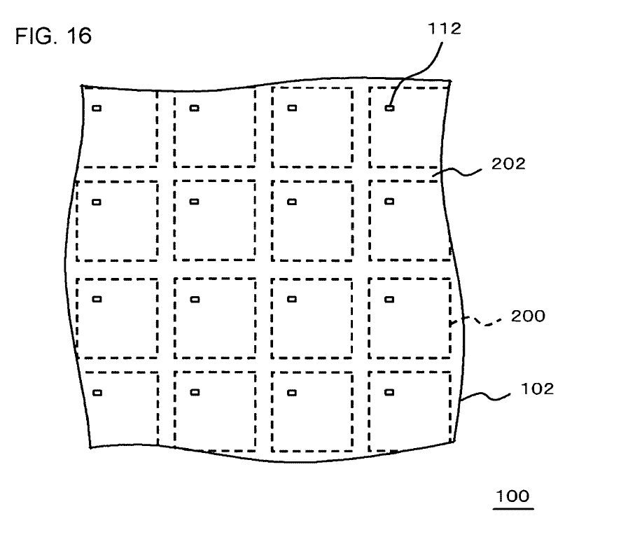

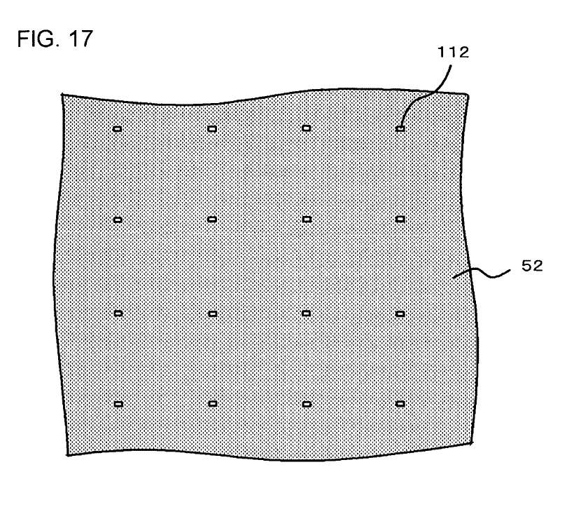

FIG. 16 is a plan view schematically illustrating a resistive element region 112 formed in a semiconductor wafer (semiconductor substrate 102). In this case, a plurality of chip formation regions 200 that are divided by a scribe line region 202 is formed on the semiconductor substrate 102. In each chip formation region 200, the resistive element region 112 is provided. As such, when a ratio of an area of the resistive element region 112 is low, if the impurity ion is implanted into only the resistive element region 112, a pattern of the resist film 52 is as shown in FIG. 17. As shown in FIG. 17, most of the region of the polysilicon layer 108 may be covered with the resist film 52. For this reason, as described with reference to FIG. 15, the charges may be collected on the resist film 52, and the impurity ion may not be implanted into the opening that corresponds to the portion of the resistive element region 112. As a result, an effective implantation dose amount of the introduced impurity ion may be decreased. In this case, an example of when the resistive element regions 112 having the same shape are provided in the plurality of chip formation regions 200 is exemplified for explanation. However, the shapes or sizes of the resistive element regions 112 may be different from each other depending on the chip formation regions 200, and the regions where the impurity ions are implanted may be roughly and densely disposed. In this case, in the portion in which the regions where the impurity ion is implanted are rough, the effective implantation dose amount is decreased. In addition, in the portion in which the regions are dense, the effective implantation dose amount is increased. As a result, a spatial variation may be generated in the effective implantation dose amount.

Accordingly, in this embodiment, in the case of including the process of implanting the impurity ion into the predetermined region of the semiconductor layer using the resist film as a mask, when a mask data ratio, which indicates a ratio of the opening with respect to the entire region of the reticle region used when the opening is formed in the resist film in order to implant the impurity ion into the predetermined region, is less than the first reference value, a dummy ion implantation region is provided in a region other than the predetermined region, such that a mask data ratio of the reticle becomes larger than the second reference value that is equal to or larger than the first reference value.

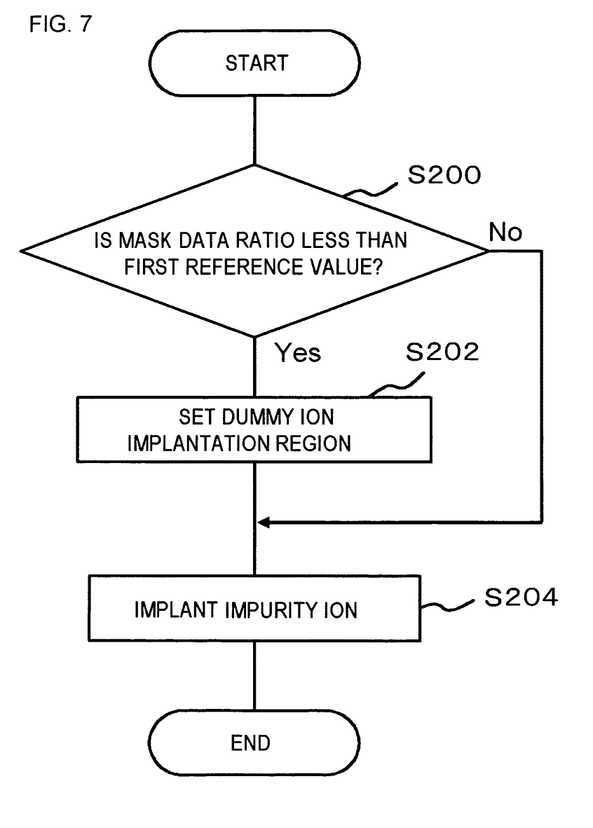

FIG. 7 is a flowchart illustrating the above sequence.

First, it is determined whether a mask data ratio, which indicates a ratio of the opening with respect to the entire region of the reticle region corresponding to a reticle to be used for forming the opening in the resist film in order to implant the impurity ion only into a target impurity implantation region, is less than a first reference value or not (S200). When the mask data ratio is less than the first reference value (YES of S200), a dummy ion implantation region is set, such that the mask data ratio of the reticle becomes larger than the second reference value that is equal to or larger than the first reference value (S202). Then, such formed reticle is used to form the resist film including openings corresponding to the first target impurity ion implantation region and the dummy ion implantation region. Next, using the resist film where the first target impurity ion implantation region and the dummy ion implantation region set in Step S202 are opened, the impurity ion is implanted (S204).

In this embodiment, the above sequence is applied to the individual impurity ion implantation processes described with reference to FIG. 1. For example, in the process of implanting the impurity ion into the resistive element region 112 that corresponds to Step S106, when the mask data ratio, which indicates the ratio of the opening with respect to the entire region of the reticle region used when the resistive element region 112 is formed, is less than the first reference value, a dummy ion implantation region where the impurity ion is simultaneously implanted is provided.

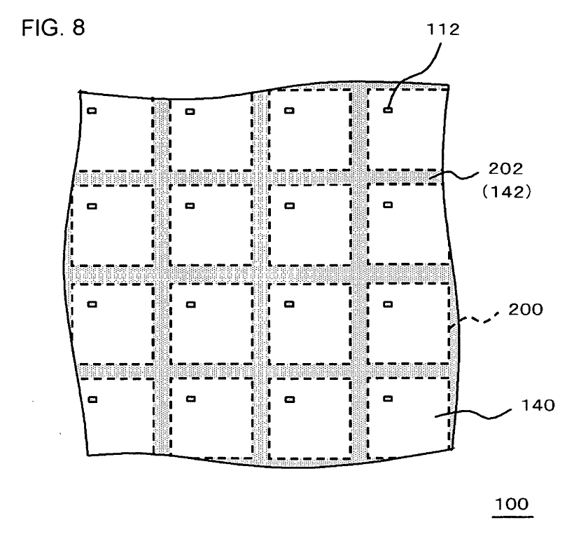

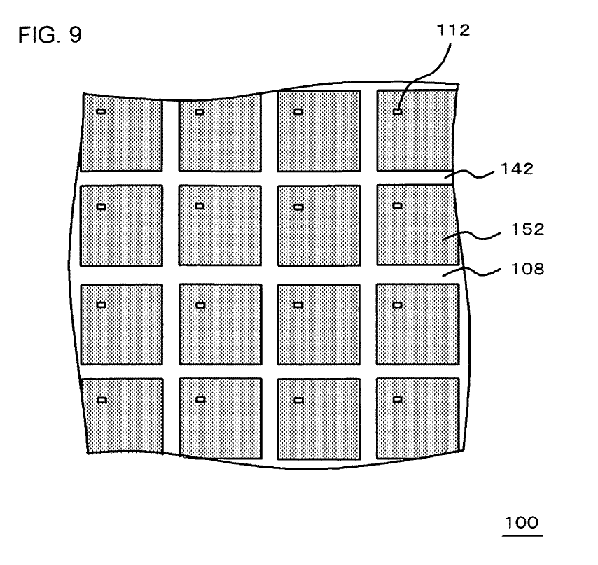

FIG. 8 is a diagram illustrating an example of when a dummy ion implantation region 142 is provided in a scribe line region 202. In this case, it is assumed that the impurity ion is implanted into a place shown by a dot. As such, when the dummy ion implantation region is provided in the scribe line region 202, a pattern of the resist film 152 is as shown in FIG. 9. In this case, as shown in FIG. 9, the polysilicon layer 108 is exposed around each chip formation region. For this reason, as shown in FIG. 14, the charges that are accumulated on the resist film 152 are moved to the polysilicon layer 108 and are not accumulated on the resist film 152. As a result, even though the opening (for example, reference numeral 152a) for the impurity ion implantation into the resistive element region 112 is narrow, the impurity ion can be implanted into the polysilicon layer 108 from the opening. Further, as such, when the dummy ion implantation region 142 is provided in the scribe line region 202, the region where the polysilicon layer 108 is exposed may be equalized. As a result, it is possible to decrease a spatial variation in the effective implantation dose amount.

Next, preferable ranges of the first reference value and the second reference value are described.

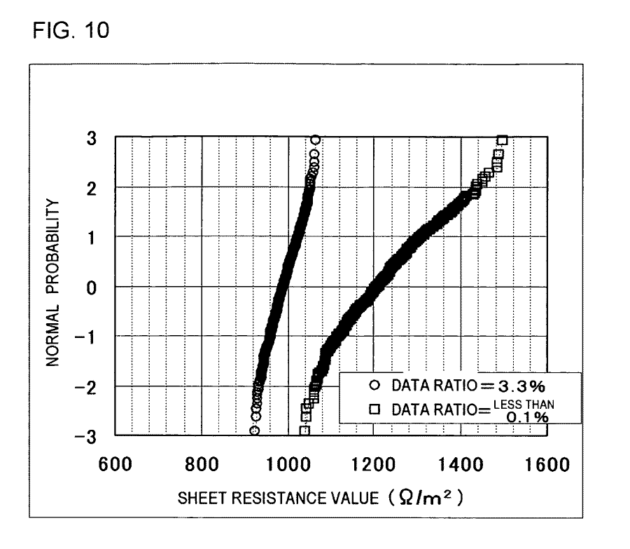

FIG. 10 is a diagram illustrating a result that is obtained by measuring a variation in sheet resistance in each place on a semiconductor substrate 102 of a resistive element region 112, when a mask data ratio is less than 0.1% and the mask data ratio is less than about 3.3%, in a process of implanting the impurity ion into the resistive element region 112, which corresponds to Step S106 of FIG. 1.

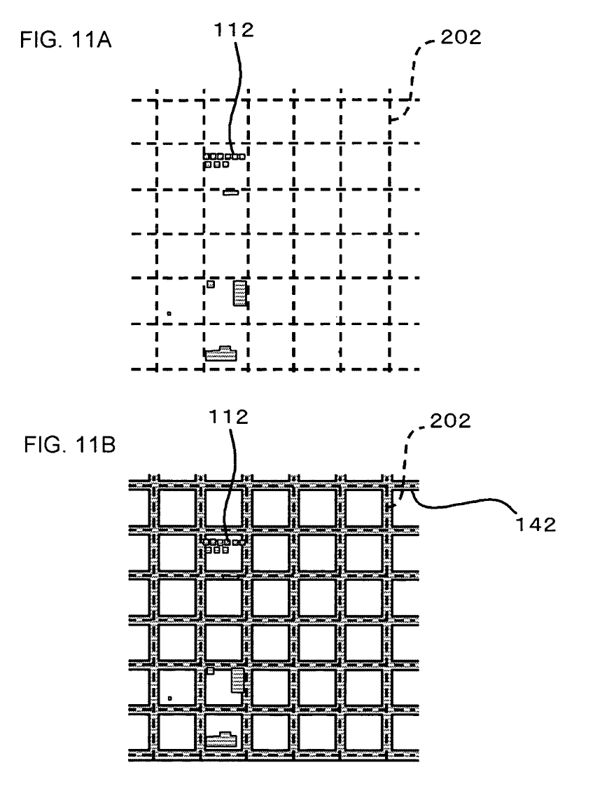

FIGS. 11A and 11B are a plan view illustrating a reticle region of a semiconductor substrate 100.

The reticle region includes a plurality of regions that are surrounded by the scribe line region 202. FIG. 11A schematically shows a pattern of a resistive element region 112, when a mask data ratio is less than 0.1% (about 0.09%). In this case, since the resistance element region 112 is arbitrarily disposed depending on a circuit, a dense and a roughness are generated in the reticle region. The ion implantation dose amount may be appropriately determined on the basis of a sheet resistance value that is necessary in the formed resistive element region 112. For example, when the sheet resistance value =1000 Ω/m² is necessary, boron is implanted by the amount of 8E14 cm⁻².

However, as shown in FIG. 10, when the mask data ratio is very low as less than 0.1%, the implantation effective dose amount in the polysilicon layer is decreased, and a resistance value is increased. For example, when the implantation dose amount is 8E14 cm⁻², the effective dose amount becomes about 7E14 cm⁻². Further, in the portion where the implantation region is rough, the effective implantation dose amount is further decreased. For example, when the implantation dose amount is 8E14 cm⁻², the effective dose amount becomes about 6E14 cm⁻². Further, in the case where the data ratio is less than 0.1%, as shown in FIG. 10, a variation in a sheet resistance value that is about 200 Ω/m² (about 25%) is generated in a shot. As a result, a variation is increased in sheet resistance in the entire region of the reticle region.

Meanwhile, FIG. 11B schematically shows a pattern of when a dummy ion implantation region 142 is provided in a scribe line region 202 and a mask data ratio is set to about 3.3%. As shown in FIG. 10, the entire resistance value is decreased and the variation is also decreased.

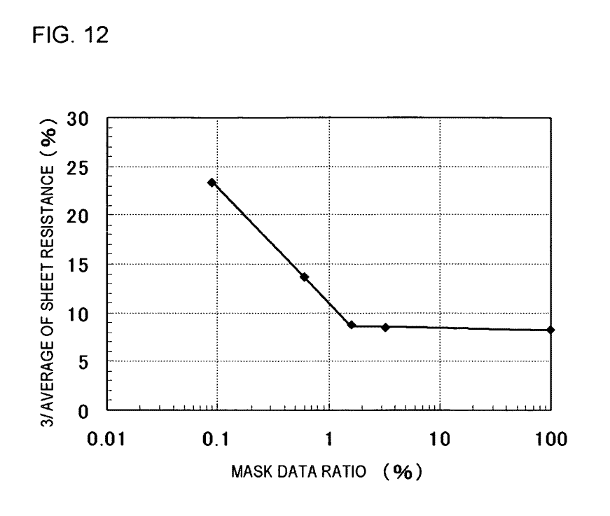

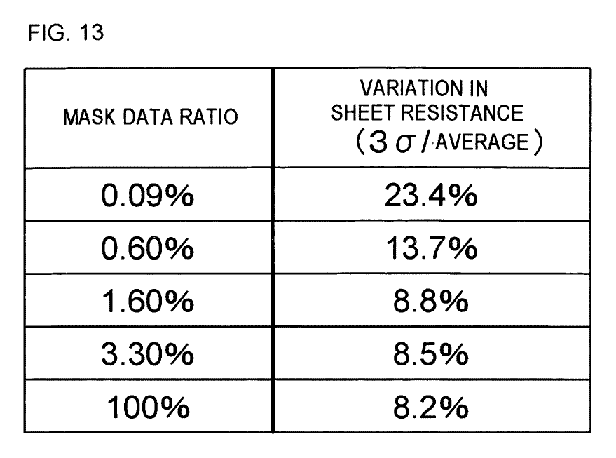

In the same way, the mask data ratio is changed to 0.60%, 1.60%, and 100%, and a variation in sheet resistance in each case is measured. This result is shown in FIGS. 12 and 13. As shown herein, when the mask data ratio is less than 0.1%, the large variation is generated in the resistance value. Meanwhile, if the mask data ratio is set to be not less than 1%, the variation in the resistance value may be suppressed to be not more than 10%.

As an example, the first reference value may be set to 0.1%. Further, as an example, the second reference value may be set to 1%. As shown in FIGS. 12 and 13, even when the mask data ratio is 0.6%, the resistant value is somewhat varied. Thus, as another example, it may be possible that the first reference value and the second reference value are set to 1% and if the mask data ratio is less than 1%, the dummy ion implantation region may be provided such that the mask data ratio becomes not less than 1%.

The effects of this embodiment will be described.

If the mask data ratio is increased, as shown in FIG. 14, the charges that are accumulated on the surface of the resist film 152 can be moved to the polysilicon layer 108, and the amount of charges that are accumulated on the resist film 152 can be decreased. As a result, the impurity ion can be implanted from the opening 152a that has the narrow width. In addition, it is possible to decrease the decrease in the effective implantation dose amount of the introduced impurity ion or the spatial variation.

The embodiment of the present invention has been described with reference to the accompanying drawings. However, the embodiment is only exemplary, and various configurations other than the above configuration may be adopted.

Although the case where the dummy ion implantation region 142 is provided in the scribe line region 202 has been exemplified in the above description, the dummy ion implantation region 142 may be provided in a region other than the scribe line region. For example, the dummy ion implantation region 142 may be provided in the portion that is removed by patterning in Step S108 of FIG. 1.

Further, the dummy ion implantation region 142 may be densely disposed in the vicinity of the place where the target impurity ion implantation regions are roughly disposed, for example, thereby decreasing the spatial variation.

In the above description, the case where the dummy ion implantation region is provided in only the process of implanting the impurity ion corresponding to Step S106 of FIG. 1 has been exemplified. However, even in the other processes, when the mask data ratio is low, it is possible to apply a process of providing the dummy ion implantation region.

It is apparent that the present invention is not limited to the above embodiment, and may be modified and changed without departing from the scope and spirit of the invention.

What is claimed is:

1. A method of manufacturing a semiconductor device comprising implanting an impurity ion into a predetermined region of a semiconductor layer using a resist film as a mask,
wherein in case when a mask data ratio for implanting said impurity ion only into said predetermined region in said resist film is less than a first reference value, a dummy ion implantation region, into which said impurity ion is also implanted in addition to said predetermined region, is added in a region other than said predetermined region so that a mask data ratio becomes larger than a second reference value which is equal to or larger than said first reference value, said mask data ratio indicating a ratio of an opening with respect to an entire region of a reticle region corresponding to the reticle.

2. The method according to claim 1,
wherein said dummy ion implantation region includes a plurality of regions which are disposed to be distributed.

3. The method according to claim 1,
wherein a plurality of chip formation regions that are divided by a scribe line region are provided in said semiconductor layer, and
said dummy ion implantation region is provided on said scribe line region.

4. The method according to claim 1,
wherein said first reference value is 0.1%.

5. The method according to claim 1,
wherein said second reference value is 1%.

6. The method according to claim 1,
wherein said first reference value and said second reference value each is 1%.

7. The method according to claim 1,
wherein, in said implanting the impurity ion, said impurity ion is implanted into a polysilicon layer formed on a substrate so as to form a polysilicon resistive element.
